(19) United States
(12) Patent Application Publication
(10) Pub. No.: US 2011/0227048 A1
(43) Pub. Date: Sep. 22, 2011

(54) Organic Electroluminescent Device

(75) Inventor: Christopher Newsome, Cambridgeshire (GB)

(73) Assignee: CAMBRIDGE DISPLAY TECHNOLOGY LIMITED

(21) Appl. No.: 13/056,113

(22) PCT Filed: Jul. 30, 2009
(86) PCT No.: PCT/GB09/01881

§ 371 Date: Apr. 15, 2011

(30) Foreign Application Priority Data
Aug. 1, 2008 (GB) 0814156.6

(51) Int. Cl. H01L 51/54

(52) U.S. Cl. 257/40; 257/E51.018

(57) ABSTRACT

An organic electroluminescent device comprising: a substrate; a first electrode disposed over the substrate for injecting charge of a first polarity; a second electrode disposed over the first electrode for injecting charge of a second polarity opposite to said first polarity; an organic electroluminescent layer disposed between the first and the second electrode; and a layer of polymer dispersed liquid crystals (PDLC), wherein said layer of PDLC does not have its own associated electrodes and drive circuitry forming a switchable PDLC cell.

### FIELD OF THE INVENTION

The present invention relates to an organic electroluminescent device and a method of manufacture thereof.

### BACKGROUND OF THE INVENTION

Organic electroluminescent devices are known, for example, from PCT/WO/13148 and U.S. Pat. No. 4,539,507. Examples of such devices are shown in FIGS. 1 and 2. Such devices generally comprise: a substrate 2; a first electrode 4 disposed over the substrate 2 for injecting charge of a first polarity; a second electrode 6 disposed over the first electrode 4 for injecting charge of a second polarity opposite to said first polarity; an organic light emitting layer 8 disposed between the first and the second electrodes; and an encapsulant 10 disposed over the second electrode 6. In one arrangement shown in FIG. 1, the substrate 2 and first electrode 4 are transparent to allow light emitted by the organic light-emitting layer 8 to pass therethrough. Such an arrangement is known as a bottom-emitting organic electroluminescent device. In another arrangement shown in FIG. 2, the second electrode 6 and the encapsulant 10 are transparent so as to allow light emitted from the organic light-emitting layer 8 to pass therethrough. Such an arrangement is known as a top-emitting organic electroluminescent device.

Variations of the above described structures are known. The first electrode may be the anode and the second electrode may be the cathode. Alternatively, the first electrode may be the cathode and the second electrode may be the anode. Further layers may be provided between the electrodes and the organic light-emitting layer in order to aid charge injection and transport. The organic material in the light-emitting layer may comprise a small molecule, a dendrimer or a polymer and may comprise phosphorescent moieties and/or fluorescent moieties. The light-emitting layer may comprise a blend of materials including light emitting moieties, electron transport moieties and hole transport moieties. These may be provided in a single molecule or in separate molecules.

FIGS. 3(a) and 3(b) show more complicated variants of organic electroluminescent device architectures.

The bottom-emitting device illustrated in FIG. 3(a) comprises: a substrate 12 (e.g. glass); a transparent anode 14 (e.g. ITO); a hole injection layer 16 (e.g. PEDT); a hole transport layer 18 (e.g. comprising a triarylamine containing polymer); an emissive layer 20 (e.g. comprising an electroluminescent polymer); and a reflective cathode structure comprising a low work function electron injecting layer 22 (e.g. barium) and a reflective layer 24 (e.g. Al).

The top-emitting device illustrated in FIG. 3(b) comprises: a substrate 26 (e.g. glass); a reflective layer 28 (e.g. Al or Ag alloy); an anode 30 (e.g. ITO); a hole injection layer 32 (e.g. PEDT); a hole transport layer 34; an emissive layer 36 (e.g. comprising an electroluminescent polymer); and a transparent cathode structure comprising a low work function electron injecting layer 38 (e.g. barium), a buffer layer 40, for example tungsten oxide as disclosed in WO2008/029103, and a transparent conductive layer 42 (e.g. ITO).

By providing an array of devices of the type described above, a display may be formed comprising a plurality of emitting pixels. The pixels may be of the same type to form a monochrome display or they may be different colours to form a multicolour display.

A problem with organic electroluminescent devices is that much of the light emitted by organic light-emitting material in the organic light-emitting layer does not escape from the device. The light may be lost within the device by internal reflection, cavity effects, wave guiding, absorption and the like. For example, it will be understood that light is emitted from the electroluminescent layer over a range of angles relative to the plane of the device. Light hitting an interface in the device at a shallow angle can be internally reflected. An optical cavity can be formed between two reflective interfaces within the device.

The cavity effects produced in an organic electroluminescent device due to reflective metal layers and interfaces between layers having large differences in refractive index (e.g. ITO to air in the top-emission structure) can result in poor optical extraction (although, on the other hand, the cavity can be optimised in order to increase light extraction). Destructive interference modes can be produced, thus lowering the overall output efficiency of the organic electroluminescent device and in some cases interference fringes are evident. Phenomena resulting in poor light extraction are described in further detail in, for example, U.S. Pat. No. 7,276,848.

FIG. 4 illustrates how light can be reflected at interfaces within an organic electroluminescent device. FIG. 4(a) corresponds to the previously described bottom-emitting architecture illustrated in FIG. 3(a). FIG. 4(b) corresponds to the previously described top-emitting architecture illustrated in FIG. 3(b). The layers are numbered with the same reference numerals as used in FIG. 3 for clarity.

As can be seen from FIG. 4(a), for a bottom-emitting device typically more than 85% of the emitted light hitting the reflective cathode is reflected in a downwards direction. Typically about 2% is reflected back from the PEDT/ITO interface and typically about 2% is reflected back from the ITO/Glass interface.

As can be seen from FIG. 4(b), for a top-emitting device typically more than 90% of the emitted light hitting the reflective anode layer is reflected in an upwards direction. Typically about 2% is also reflected upwards from the ITO/PEDT interface. However, between 0 and 85% of the light is reflected back from the Ba/Buffer interface in the cathode structure and typically 11% is reflected back from the ITO/air interface at the top of the device.

Additional loss in top-emitting structures occurs due to the fact that the refractive index mismatch at the ITO/air interface is larger than that at the ITO/electron injecting electrode interface. In addition, the reflective anode layer gives rise to the formation of resonant modes of larger intensity than in the bottom-emission case.

Optical extraction for an organic electroluminescent device is a critical element to improve the efficiency and image quality of a display. Although the internal efficiency of an organic electroluminescent device may be improved via new emitter material design, a substantial part of the light that is produced from the emitter layer may be lost through poor optical extraction.

One way of increasing the amount of light which escapes from an organic electroluminescent device is to incorporate an optical scattering element(s) in the device architecture in order to remove, or significantly reduce, internal reflection of light within the device and thereby improve external efficiency of the device.

Techniques such as the addition of light scattering elements or micro-lens arrays to organic electroluminescent devices have been implemented in the prior art in order to improve the extraction of light.

U.S. Pat. No. 5,955,837 discloses an organic electroluminescent device comprising a light-scattering layer consisting of a layer of inorganic particles, e.g. a mono layer of TiO₂ particles.

US 2007/0108900 discloses an organic electroluminescent device comprising a light-scattering layer selected from one of a roughened glass surface, a layer of transparent particles, a polymer film containing a dispersion of inorganic particles or a co-polymer film containing multiple phases.

U.S. Pat. No. 7,276,848 discloses an organic electroluminescent device comprising a light-scattering layer selected from one of a roughened surface, a layer of inorganic particles, and a polymer film containing a dispersion of inorganic particles

It is an aim of the present invention is to provide an organic electroluminescent device comprising an alternative light-scattering layer to those described above. It is an aim of certain embodiments of the present invention to provide an organic electroluminescent device comprising a light-scattering material which is easy to manufacture and readily processable to form a layer of an organic electroluminescent device without causing any damage to other layers of the organic electroluminescent device and using deposition techniques already utilized in organic electroluminescent device manufacture. It is a further aim of certain embodiments of the present invention to provide an organic electroluminescent device comprising a light-scattering layer whose scattering properties can be readily selected and even tuned in-situ according to the amount of scattering desired for a particular device architecture or use.

### SUMMARY OF THE INVENTION

In accordance with the present invention there is provided an organic electroluminescent device comprising a light-scattering layer made of a polymer dispersed liquid crystal (PDLC).

PDLCs are known. They comprise a polymer matrix with a dispersion of liquid crystal droplets disposed therein. In the prior art, PDLCs are used as light-shutters by disposing the PDLC between two electrodes to form a cell. When no voltage is applied across the cell there is no overall orientation of the liquid crystal molecules within the droplets and light incident on the cell will be affected according to both the refractive index of the polymer matrix and the refractive index of the unaligned liquid crystal, which is different to the refractive index of the polymer matrix. Light is scattered at the interface between the droplets and the polymer matrix due to the difference in refractive index between the randomly orientated liquid crystal molecules and the polymer matrix. The cell appears opaque or cloudy in this state. When a voltage is applied across the cell the liquid crystal molecules within each droplet are aligned with the applied field. The refractive index of the liquid crystal molecules in the direction of the applied field is changed due to the alignment of the liquid crystal molecules. The polymer matrix and the liquid crystal materials are selected such that in the aligned state, the refractive index of the liquid crystal in the aligned direction is equal to the refractive index of the polymer matrix. As such, light incident on the PDLC in the aligned direction is not scattered and the cell appears transparent or substantially transparent. As such, these PDLCs can be used as privacy windows which can be switched between a transparent and an opaque state. If an addressable array of such cells is provided with a back light then a display device can be formed in a similar manner to a conventional liquid crystal display. The switchable light-scattering property of PDLCs for use as a light-shutter is discussed, for example, in Montgomery et. al., “Light scattering from polymer-dispersed liquid crystal films: Droplet size effects”, J. Chem. Phys. 69 (3), 1991 and in West et. al., “Haze-free polymer dispersed liquid crystals utilizing linear polarizers”, Appl. Phys. Lett. 61 (17), 1992.

It is also known from JP 2006/276089 to incorporate a PDLC light shutter cell into an organic electroluminescent display device. This document is directed to the problem of ambient light being reflected back from non-emitting pixels of the display in use. Addressable PDLC cells are provided adjacent the array of light emissive pixels such that light can be blocked or transmitted as required in order to solve this problem. However, one disadvantage in this arrangement is that additional electrodes and driving circuitry needs to be incorporated into the device for driving the PDLC cells independently from the organic electroluminescent pixels, thus complicating the device design.

The present invention differs from the previously described uses of a PDLC in that the present application does not require switching of the PDLC between aligned and non-aligned states. Rather, the PDLC is provided so as to remain in substantially the same state to scatter light in order to reduce internal reflection and/or cavity effects and thus increase light output from the device.

In light of the above, in accordance with a first aspect of the present invention there is provided an organic electroluminescent device comprising: a substrate; a first electrode disposed over the substrate for injecting charge of a first polarity; a second electrode disposed over the first electrode for injecting charge of a second polarity opposite to said first polarity; an organic electroluminescent layer disposed between the first and the second electrode; and a layer of polymer dispersed liquid crystals (PDLC), wherein said layer of PDLC does not have its own associated electrodes and drive circuitry forming a switchable PDLC cell.

The present inventors have identified that a PDLC layer can be used as a light-scattering layer for increasing light output from an organic electroluminescent device in a similar manner, for example, to a polymer film containing a dispersion of inorganic particles as disclosed in the prior art arrangements discussed in the background section. PDLC layers can be easily manufactured and readily processed to form a layer of an organic electroluminescent device without causing any damage to other layers of the organic electroluminescent device and using deposition techniques already utilized in organic electroluminescent device manufacture. Furthermore, the light scattering properties of a PDLC layer can be readily selected and even tuned in-situ according to the amount of scattering desired for a particular device architecture or use.

The PDLC layer can be made so as to be transmissive, or substantially transmissive, to light emitted by the organic electroluminescent layer. The PDLC layer according to embodiments of the present invention may be designed to ensure that the amount of scattering is sufficient to reduce internal reflection and cavity effects while being not too high as to render the layer opaque or cloudy.

There are several possible ways to ensure that the amount of scattering is sufficient to reduce internal reflection and cavity effects while being not too high as to render the layer opaque or cloudy. This is because the amount of light which is scattered by the PDLC is sensitive to a number of different parameters which may be tuned in order to achieve the desired effect. These parameters include: the degree of alignment of the liquid crystal molecules in the PDLC; the thickness of the PDLC layer; the size of the liquid crystal droplets in the PDLC; the volume fraction of liquid crystal droplets in the polymer matrix; and the average difference in refractive index between the liquid crystal droplets and the polymer matrix for a particular degree of alignment.

Accordingly, at least the following possibilities, and combinations thereof, exist for achieving the desired functional effect of scattering light emitted from the organic electroluminescent layer in sufficient quantities to reduce internal reflection and cavity effects while not scattering light too much as to render the layer opaque or cloudy:

1. Tune the Thickness of the PDLC Layer.

The PDLC layer can be made thin enough to be transparent, or substantially transparent, to light emitted by the organic electroluminescent layer. The PDLC layer is preferably less than 10 μm, more preferably less than 6 μm, more preferably still less than 3 μm, and most preferably less than 2 μm. If the layer becomes too thin relative to the wavelength of light emitted by the organic electroluminescent layer then no or little scattering of light occurs. If efficient light scattering is required over the whole visible spectrum (e.g. for red, green and blue emissive pixels) then the PDLC layer will preferably be 0.7 μm or greater in thickness, most preferably 1 μm or greater (e.g. in the range 1-2 μm). However, since efficient light scattering over the whole visible spectrum is not necessarily required in certain embodiments of the present invention then it is possible to provide a thinner PDLC layer of, for example, less than 1 μm, less than 0.7 μm, and even as low as about 0.5 μm. Such ultra thin PDLC layers will not scatter red and green light efficiently. However, they will still scatter blue light. This is particularly advantageous for organic electroluminescent devices as the lifetime of blue organic electroluminescent materials is significantly lower than for red and green organic electroluminescent materials. The lifetime of blue emissive pixels is thus a limiting factor on the lifetime of organic electroluminescent displays. If the blue light output from an organic electroluminescent display is increased using an ultra thin PDLC layer then the blue pixels can be driven more gently thus increasing the lifetime of the blue pixels and thus increasing the lifetime of the display. As such, in accordance with certain embodiments of the present invention an ultra thin layer of PDLC is incorporated into an organic electroluminescent device to increase the lifetime of blue emissive pixels disposed therein.

2. Tune the Size of the Liquid Crystal Droplets in the PDLC Layer.

The droplet size can be made small enough such that the PDLC layer is transmissive, or substantially transmissive, to light emitted by the organic electroluminescent layer. The size of the liquid crystal droplets within a PDLC layer will vary. The distribution in size of the droplets will depend on the manufacturing process. Preferably, at least 50% of the droplets, more preferably at least 70% of the droplets, and more preferably still at least 90% of the droplets will have a diameter of 2 μm or less. As previously discussed in relation to layer thickness, if the diameter of the droplets becomes too small relative to the wavelength of light emitted by the organic electroluminescent layer then little or no scattering of light occurs. If efficient light scattering is required over the whole visible spectrum (e.g. for red, green and blue emissive pixels) then the droplet diameter will preferably be 0.7 μm or greater (e.g. at least 50%, 70% or 90% of droplets in the range 1-2 μm). However, as previously discussed in relation to layer thickness, since efficient light scattering over the whole visible spectrum is not necessarily required in certain embodiments of the present invention then it is possible to provide a PDLC layer with smaller liquid crystal droplets with 50%, 70% or 90% having a diameter of, for example, less than 1 μm, less than 0.7 μm, and even as low as about 0.5 μm. Such ultra small droplet PDLC layers will not scatter red and green light efficiently. However, they will still scatter blue light and may be used to increase the lifetime of blue emissive pixels.

In one arrangement, the layer thickness and droplet size may be selected in order to form a PDLC layer comprising a mono layer of droplets. The PDLC layer may even be deposited so as to form non-spherical droplets by, for example, compressing to form oval shaped droplets which have a width greater than their height. This arrangement can result in a thinner PDLC layer. In this case, the previously discussed ranges for the diameter of the droplets should be applied to the width of the droplets in the plane of the device.

3. Tune the Volume Fraction of the Liquid Crystal Droplets in the PDLC Layer.

The volume fraction should be small enough such that the PDLC layer is transmissive, or substantially transmissive, to light emitted by the organic electroluminescent layer. Reducing the volume fraction of liquid crystal droplets will generally reduce the amount of light scattering. The volume fraction may be selected to ensure sufficient scattering in order to reduce internal reflection and/or cavity effects while not scattering light too much as to render the layer opaque or cloudy. Typical values for the volume fraction of liquid crystal droplets in the PDLC lie in the range 5-50%.

4. Tune the Difference in Refractive Index Between the Liquid Crystal and the Polymer Matrix Materials.

The larger the difference in refractive index between the liquid crystal and the polymer matrix materials, the more light scattering will occur. Materials may be selected such that the difference in refractive index is large enough to ensure sufficient scattering in order to reduce internal reflection and/or cavity effects while not scattering light too much as to render the layer opaque or cloudy. Typically, for light-shutter applications, the refractive index of the liquid crystal material in the aligned state is equal, or substantially equal, to the refractive index of the polymer matrix material in the aligned direction while the refractive index of the liquid crystal material in the non-aligned state is significantly different from the refractive index of the polymer matrix. Because the present invention is concerned with scattering light, this rather strict requirement is not a necessity. The refractive index of the liquid crystal material in the aligned state may be different to the refractive index of the polymer matrix material, e.g. a difference in refractive index of >0.1 or >0.2 at 20° may be provided. Similarly, the difference between the refractive index of the liquid crystal material in the non-aligned state and the polymer matrix is not required to be as large as for light shutter arrangements in accordance with certain embodiments of the present invention, e.g. <0.2 or <0.1 at 20° C. (although the refractive index difference should be larger for thinner films). This will increase the range of liquid crystal materials which may be utilized in the present invention.

Because the liquid crystal molecules are not required to be switchable between aligned and unaligned states in embodiments of the present invention then the viscosity of the liquid crystal material can be higher than that for light shutter arrangements which require a relatively low viscosity for switchability. Again, this will increase the range of liquid crystal materials which may be utilized in the present invention. Depending on the method of manufacture, the viscosity of the liquid crystal material may be required to be low enough to allow phase separation of the liquid crystal material from the polymer matrix material in order to form droplets of a suitable size. Typically the viscosity of the liquid crystal may be in the range 60 to 90 cP at 20° C.

Given that the liquid crystal molecules do not need to be switchable in the final device, according to one possibility the liquid crystal may even be solid at 20° C. The PDLC may be formed at higher temperatures at which the liquid crystal can phase separate to form suitably sized droplets and then when cooled the order of the liquid crystal molecules is frozen into the PDLC at normal operating conditions of the device. In one embodiment, the PDLC layer may be heated to liquefy the droplets, provided with an electrode to align the droplets, and then allowed to cool to freeze the alignment in place. The electrode is removed before or after cooling of the layer.

Preferably, the organic electroluminescent device is a top-emitting (transparent cathode) device, and the PDLC layer is provided over the transparent cathode. As shown in FIGS. 4(a) and 4(b), the present applicant has found that light loss due to internal reflection and lossy cavity modes is greater in top-emitting devices than in bottom-emitting device.

Preferably the first electrode is an anode and the second electrode is a cathode. The cathode may comprise a layer of electron-injecting material such as a low workfunction (less than 3.5 eV, preferably less than 3 eV) metal (e.g. barium) or metal compound (e.g. lithium fluoride) with a metal capping layer such as a high workfunction (>3.5 eV, preferably >4 eV) metal, e.g. aluminium, thereover. The layer of electron-injecting material is preferably less than 10 nm thick and more preferably is approximately 5 nm thick. Such a cathode will typically be reflective, however the cathode may be transparent if the electron injecting layer and capping layer are both sufficiently thin, e.g. in the range of 5-10 nm. An alternative cathode utilizes a layer of barium with a layer of silver thereover. Each of these layers is preferably less than 10 nm thick and more preferably each layer is approximately 5 nm thick. This cathode is more transparent than the aforementioned Barium/Aluminium arrangement. A further alternative transparent cathode structure comprises an electron injection layer and a capping layer of transparent conductive oxide, in particular indium tin oxide (ITO). In this case, a sputter barrier layer is preferably provided between ITO layer and the underlying layers of the device in order to prevent sputter damage to said underlying layers. A suitable sputter barrier should also allow for efficient electron injection may be an inorganic layer, such as a metal selenide or sulphide (e.g. ZnS or ZnSe) or an organic layer, in particular a doped layer such as a metal-doped fullerene layer. A thin, transparent electron injection layer such as a layer of low workfunction metal (e.g. alkali earth metal) or metal oxide or metal fluoride may be provided between the organic layer(s) of the device and the sputter barrier layer.

The PDLC scattering layer can be tuned according to the emission colour of the organic electroluminescent layer. In a full colour display, different PDLC structures can be provided for the different coloured pixels if desired.

Preferably the organic electroluminescent layer and/or the PDLC layer is deposited from solution by, for example, ink jet printing or spin coating.

### BRIEF DESCRIPTION OF THE DRAWINGS

Embodiments of the present invention will now be described by way of example only with reference to the accompanying drawings, in which:—

FIG. 1 shows a known structure of a bottom-emitting organic electroluminescent device;

FIG. 2 shows a known structure of a top-emitting organic electroluminescent device;

FIGS. 3(a) and 3(b) show further known structures for bottom-emitting and top-emitting organic electroluminescent devices respectively;

FIGS. 4(a) and 4(b) illustrate how emitted light is internally reflected within the devices illustrated in FIGS. 3(a) and 3(b) respectively;

FIG. 5 shows a top-emitting organic electroluminescent device comprising a PDLC light scattering layer in accordance with an embodiment of the present invention;

FIGS. 6(a) and 6(b) illustrate how light is scattered in two different PDLC light scattering layers according to embodiments of the present invention.

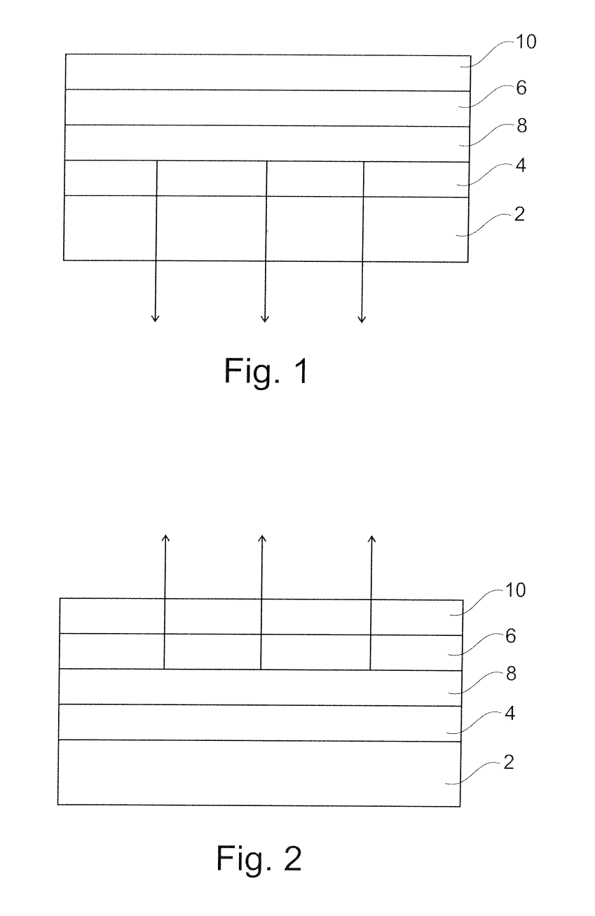

### DETAILED DESCRIPTION OF EMBODIMENTS OF THE PRESENT INVENTION

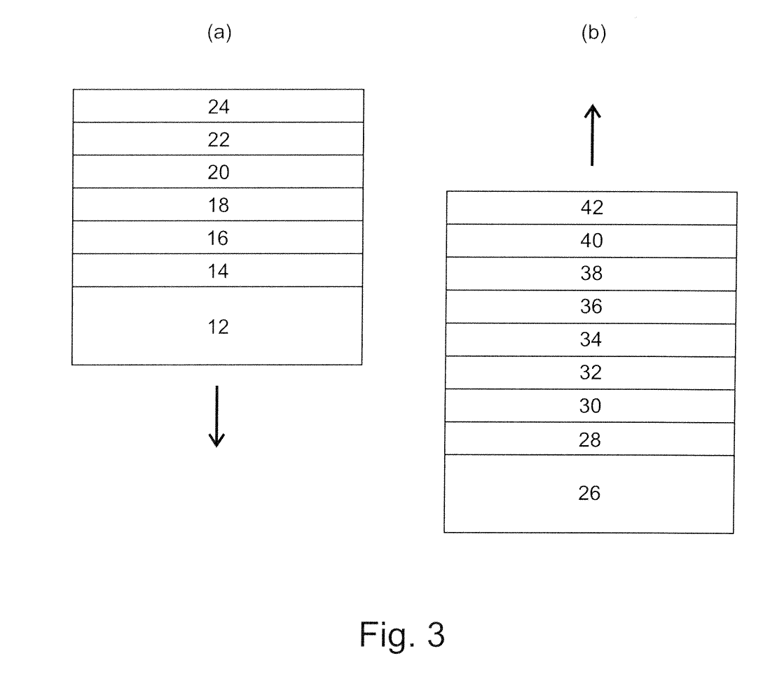

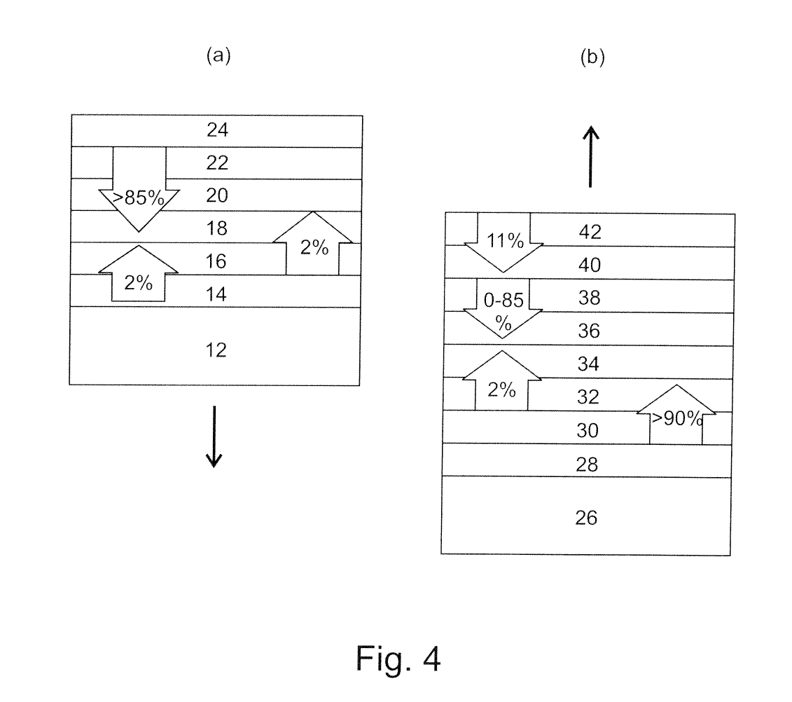

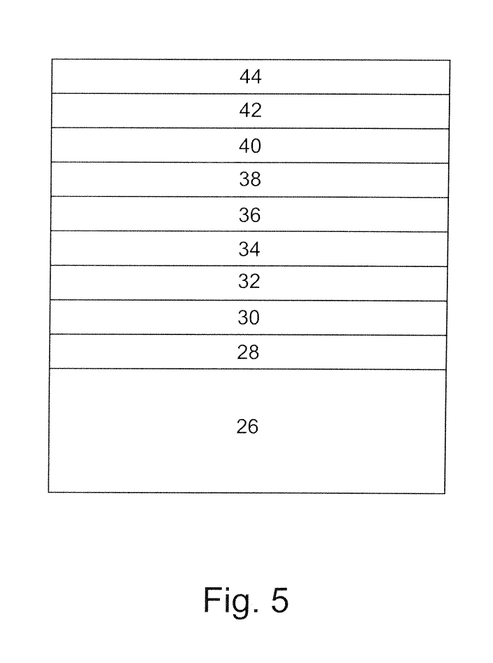

FIG. 5 shows a top-emitting organic electroluminescent device comprising a PDLC light scattering layer in accordance with an embodiment of the present invention. The top-emitting device structure is similar to that illustrated in FIGS. 3(b) and 4(b) and like reference numerals have been used for corresponding layers. The device structures comprises: a substrate 26 (e.g. glass); a reflective layer 28 (e.g. Al or Ag alloy); a hole injecting layer 30 (e.g. ITO); a hole injection layer 32 (e.g. PEDT); a hole transport layer 34 (e.g. comprising a triarylamine containing polymer); an emissive layer 36 (e.g. comprising an electroluminescent polymer); and a transparent cathode structure comprising a low work function electron injecting layer 38 (e.g. Ba), a buffer layer 40, and a transparent conductive layer 42 (e.g. ITO).

In the arrangement illustrated in FIG. 5 a PDLC light scattering layer 44 is provided over the transparent conductive layer 42.

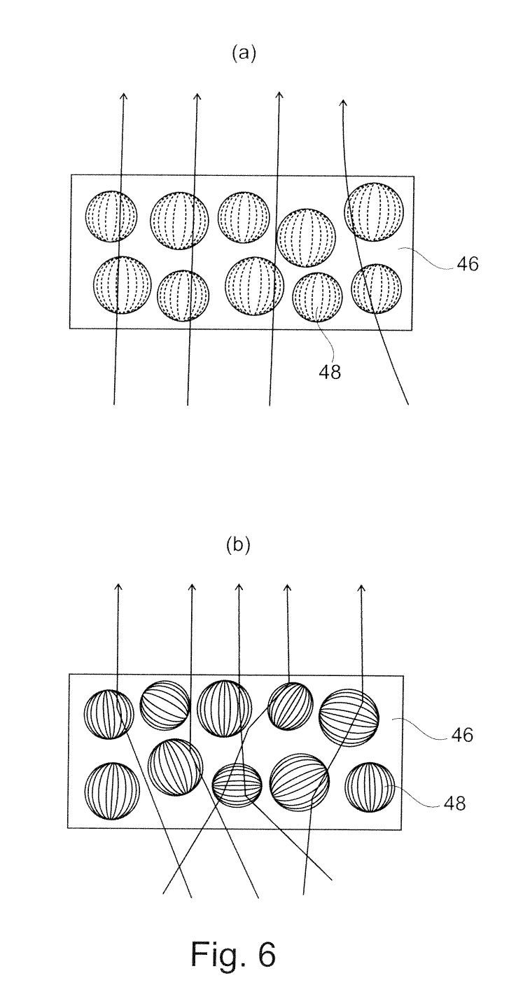

FIGS. 6(a) and 6(b) illustrate how light is scattered in two different PDLC light scattering layers according to embodiments of the present invention.

In the arrangement illustrated in FIG. 6(a), the PDLC has been tuned to a fully aligned state. In this case, the polymer matrix 46 and the liquid crystal material 48 may be selected such that the refractive index of the liquid crystal 48 in the aligned direction is equal to the refractive index of the polymer matrix 46, such that light emitted in the aligned direction is not scattered whereas light emitted in other angular directions will be scattered. As previously described, light is emitted from the electroluminescent layer over a range of angles relative to the plane of the device. Light hitting an interface in the device at a shallow angle can be internally reflected. However, this light will be scattered by the PDLC, even if the PDLC is fully aligned in a direction perpendicular to the plane of the device thus reducing internal reflection and/or cavity effects.

Alternatively, as illustrated in FIG. 6(b), the PDLC may be provided in a non-aligned state with the liquid crystal material 48 in each of the droplets orientated in different directions in the polymer matrix 46. In this arrangement, light emitted from the organic electroluminescent layer in all angular directions will be scattered.

In order to attain the light scattering properties as described, it is important that the polymer-liquid crystal mixture is such that the liquid crystal is forced to phase separate from the polymer to form droplets. This can be achieved, for example, by using a precursor polymer that initially is homogenised with the liquid crystal. Then during a conversion or drying phase of the polymer the liquid crystal phase separates to form discrete liquid crystal droplets dispersed in the polymer. This technique is known as polymerisation induced phase separation (PIPS). The polymerisation process may be initiated by heat (e.g. an epoxy resin/curing agent) or by UV light (e.g. an acrylate). A UV cross-linking type polymer matrix may be utilized in order to form a crosslinked matrix at ambient temperatures.

As a specific example, polymers such as Norland Optical Adhesives are widely used as the polymer matrix. These typically have a viscosity of a few hundred centipoise and are crosslinked by UV radiation. Crosslinkable polymers such as SU-8 can be used as an alternative to high viscosity optical adhesives such that spin coating is possible.

Liquid phase deposition methods for forming the PDLC light-scattering layer are preferred as these are compatible with liquid phase deposition methods used in organic electroluminescent devices, particularly polymer light emitting devices. For example, U.S. Pat. No. 6,866,887 describes the formation of a PDLC film by spin coating with controlled evaporation rate to achieve phase separation. In addition, inkjet printing of PDLC mixtures has also been described by Heilmann (http://www.vtt.fi/liitetiedostot/cluster5_metsa_kemia_ymparisto/IST%20NIP%202005%20Heilmann.pdf). Here, Norland optical adhesive 65 was inkjet printed from an anisol based ink. Merck E7 and E8 liquid crystals were used.

There are a wide selection of commercially available liquid crystal molecules and mixtures. A number of organic crystal materials may be beneficial, provided that the dispersion of the organic crystals is on a similar scale to that of the liquid crystal domains. Patterning of a PDLC layer is possible using techniques such as etching, photolithographic patterning and inkjet printing.

While this invention has been particularly shown and described with reference to preferred embodiments thereof, it will be understood by those skilled in the art that various changes in form and details may be made therein without departing from the scope of the invention as defined by the appended claims.

1. An organic electroluminescent device comprising:
a substrate;
a first electrode disposed over the substrate for injecting charge of a first polarity;
a second electrode disposed over the first electrode for injecting charge of a second polarity opposite to said first polarity;
an organic electroluminescent layer disposed between the first and the second electrode; and
a layer of polymer dispersed liquid crystals (PDLC), wherein said layer of PDLC does not have its own associated electrodes and drive circuitry forming a switchable PDLC cell.

2. An organic electroluminescent device according to claim 1, wherein the PDLC layer is adapted to scatter light emitted by the organic electroluminescent layer to a sufficient degree to reduce internal reflection and/or cavity effects while remaining transmissive, or substantially transmissive, to light emitted by the organic electroluminescent layer.

3. An organic electroluminescent device according to claim 1, wherein the PDLC is provided in an aligned state with liquid crystal molecules in each droplet of the PDLC aligned in a direction perpendicular to the plane of the device.

4. An organic electroluminescent device according to claim 1, wherein the PDLC are provided in a non-aligned state with liquid crystal molecules in each droplet of the PDLC oriented in different directions.

5. An organic electroluminescent device according to claim 1, wherein the PDLC are provided in a non-aligned state with liquid crystal molecules in each droplet of the PDLC oriented in random directions.

6. An organic electroluminescent device according to claim 1, wherein the PDLC layer has a thickness of 0.5 μm-10 μm.

7. An organic electroluminescent device according to claim 6, wherein the PDLC layer has a thickness of 0.7 μm or more.

8. An organic electroluminescent device according to claim 1, wherein at least 50% of liquid crystal droplets in the PDLC layer have a diameter of 2 μm or less.

9. An organic electroluminescent device according to claim 8, wherein at least 50% of liquid crystal droplets in the PDLC layer have a diameter of 0.7 μm or more.

10. An organic electroluminescent device according to claim 1, wherein the PDLC layer has a thickness of 0.5 μm-1 μm.

11. An organic electroluminescent device according to claim 10, wherein at least 50% of liquid crystal droplets in the PDLC layer have a diameter of 0.5 μm-1 μm.

12. An organic electroluminescent device according to claim 10, wherein the organic electroluminescent layer comprises a blue emissive material.

13. An organic electroluminescent device according to claim 1, wherein the PDLC layer comprises a mono layer of droplets.

14. An organic electroluminescent device according to claim 1, wherein the PDLC layer comprises oval shaped droplets having a width in the plane of the device which is greater than their height.

15. An organic electroluminescent device according to claim 1, wherein the PDLC layer has a volume fraction of liquid crystal droplets in the range 5%-50%.

16. An organic electroluminescent device according to claim 1, wherein the PDLC layer comprises liquid crystal material and polymer matrix material which have different refractive indices in an aligned direction.

17. An organic electroluminescent device according to claim 16, wherein the difference in refractive index is >0.1 at 20°.

18. An organic electroluminescent device according to claim 1, wherein the PDLC layer comprises liquid crystal material having a viscosity in the range 60 cP to 90 cP at 20° C.

19. An organic electroluminescent device according to claim 1, wherein the PDLC layer comprises liquid crystal material which is solid at 20° C.

20. An organic electroluminescent device according to claim 1, wherein the PDLC layer is disposed over the second electrode.

21. An organic electroluminescent device according to claim 1, wherein the organic electroluminescent device is a top-emitting device, the first electrode comprises a reflective anode, and the second electrode comprises a transparent cathode.

22. An organic electroluminescent device according to claim 6, wherein the PDLC layer has a thickness of 1.0 μm or more.
